(19) United States
(12) Patent Application Publication
(10) Pub. No.: US 2017/0263838 A1
(43) Pub. Date: Sep. 14, 2017

(54) THERMOELECTRIC STRUCTURE

(71) Applicant: National Taiwan University of Science and Technology, TAIPEI CITY (TW)

(72) Inventors: Jinn CHU, TAIPEI CITY (TW); Hsin-Jay WU, TAIPEI CITY (TW); Chia-Chi YU, TAIPEI CITY (TW)

(21) Appl. No.: 15/230,491

(22) Filed: Aug. 8, 2016

(30) Foreign Application Priority Data
Mar. 11, 2016 (TW) 105107690

(51) Int. Cl. H01L 35/08; H01L 35/34

(52) U.S. Cl. CPC H01L 35/08; H01L 35/34; H01L 35/16

(57) ABSTRACT

The present disclosure provides a thermoelectric structure including a thermoelectric substrate and a barrier layer covering the thermoelectric substrate. A material of the barrier layer is metallic glass. The thermoelectric structure of the present disclosure may apply to a medium-temperature (about 400K to about 800K) thermoelectric module to effectively block the diffusion of the thermoelectric substrate.

### RELATED APPLICATIONS

This application claims priority to Taiwan Application Serial Number 105107690, filed Mar. 11, 2016, which is herein incorporated by reference.

### BACKGROUND

Field of Disclosure

The present disclosure relates to a thermoelectric module. More particularly, the present disclosure relates to a thermoelectric structure used for the thermoelectric module.

Description of Related Art

Thermoelectric substrate and thermoelectric modules are important in the green energy industry. Currently, the thermoelectric modules operated at room temperature are often used for cooling, and mainly use a low-melting temperature metal as the solder, such as tin, to connect the thermoelectric substrates and the copper electrodes. However, the diffusion bonding is employed in medium- or high-temperature thermoelectric modules, which lead to the interdiffusion between the thermoelectric substrates and the copper electrodes due to the elevated temperature or current. Therefore, a diffusion barrier layer is often introduced between the thermoelectric substrate and the copper electrode in order to avoid the diffusion of the atoms. The diffusion barrier layer is generally crystalline material, such as nickel or its alloys. The grain boundaries distributed in the crystalline materials serve as pathways to provide the atoms to diffuse, especially at a temperature greater than 300° C., and thereby produces intermetallic compounds which may reduce the reliability and the durability of the thermoelectric module.

### SUMMARY

Large amounts of waste heat are produced at a temperature greater than 300° C., which can be used as the regenerative power of the thermoelectric modules. However, a generally crystalline diffusion barrier layer is easily reacted with a thermoelectric substrate at the temperature greater than 300° C. to produce an intermetallic compound having the poor mechanical properties, and thereby damage the reliability and the durability of the thermoelectric module.

In view of the issue un-met in the art, the present disclosure provides a thermoelectric structure, which can apply to a thermoelectric module and effectively inhibit the diffusion between different layers at the temperature greater than 300° C.

The present disclosure provides a thermoelectric structure including a thermoelectric substrate and a barrier layer covering the thermoelectric substrate. A material of the barrier layer is metallic glass.

In some embodiments of the present disclosure, the metallic glass includes zirconium (Zr), iron (Fe), titanium (Ti), nickel (Ni), tungsten (W) and a combination thereof.

In some embodiments of the present disclosure, the metallic glass is selected from a group consisting of ZrCu, ZrCuAlNi, ZrCuAlAg, ZrCuAlTa, ZrTiCuNiBe, ZrCuAlNiNb, ZrTiCuNiAl, ZrCuAl, ZrNiAl, ZrTiBe and ZrYAlNi.

In some embodiments of the present disclosure, the metallic glass is selected from a group consisting of FeMoCB, FeZrB, FePBSi, FeAlGaPCB, FeBY, FeBNb and FeCrMoCB.

In some embodiments of the present disclosure, the metallic glass is selected from a group consisting of TiHfNiCu, TiNiCu, TiZrNiCuBe and TiZrCuNbCo.

In some embodiments of the present disclosure, the metallic glass is selected from a group consisting of NiNb, NiFeNbSn, NiNbSn and NiZrTiSiSn.

In some embodiments of the present disclosure, the metallic glass is selected from a group consisting of WSiN, WRuB, WReB and WNiB.

In some embodiments of the present disclosure, the metallic glass is ZrₐCu_{b}Al_{c}Ni_{d}, a=55±10at %, b=30±5at %, c=10±5at % and d=10±5at %.

In some embodiments of the present disclosure, the barrier layer has a thickness in a range of 50 nm to 200 nm.

In some embodiments of the present disclosure, the thermoelectric substrate is selected from a group consisting of PbTe, CoSb₃, AgSbTe₂, Zn₄Sb₃ Pb—Ag—Sb—Te, GeTe, Te—Sb—Ge—Ag, Ag—Bi—Se—Ge, AgSbSeₓTe₂₋ₓ and YbₓCo₄Sb₁₂, and 0≦x≦1.

The thermoelectric structure of the present disclosure can effectively inhibit the diffusion between different layers at the temperature greater than 300° C. without affecting its reliability and durability, and has a broad applicability.

These and other features, aspects, and advantages of the present disclosure will become better understood with reference to the following description and appended claims.

It is to be understood that both the foregoing general description and the following detailed description are by examples, and are intended to provide further explanation of the invention as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure could be more fully understood by reading the following detailed description of the embodiment, with reference made to the accompanying drawings as follows:

FIG. 1 illustrates a perspective view of a thermoelectric structure according to some embodiments of the present disclosure.

FIG. 2A is an image of a thermoelectric substrate coated with metallic glass after annealing 5 days at 400° C. under a cross-section transmission electron microscope.

FIG. 2B is a line scan analysis chart along an arrow A to A′ of FIG. 2A.

FIG. 3A is an image of a thermoelectric substrate coated with nickel (Ni) after annealing 5 days at 400° C. under a cross-section transmission electron microscope.

FIG. 3B is a line scan analysis chart along an arrow B to B′ of FIG. 3A.

### DETAILED DESCRIPTION

The following embodiments are disclosed for detailed description. For illustration clarity, many details of practice are explained in the following descriptions. However, it should be understood that these details of practice do not intend to limit the present invention. That is, these details of practice are not necessary in parts of embodiments of the present invention. Furthermore, for simplifying the drawings, some of the conventional structures and elements are shown with schematic illustrations.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

In order to solve aforementioned problems in the art, the present disclosure provides a thermoelectric structure. The thermoelectric structure includes a thermoelectric substrate and a barrier layer covering the thermoelectric substrate. A material of the barrier layer is metallic glass.

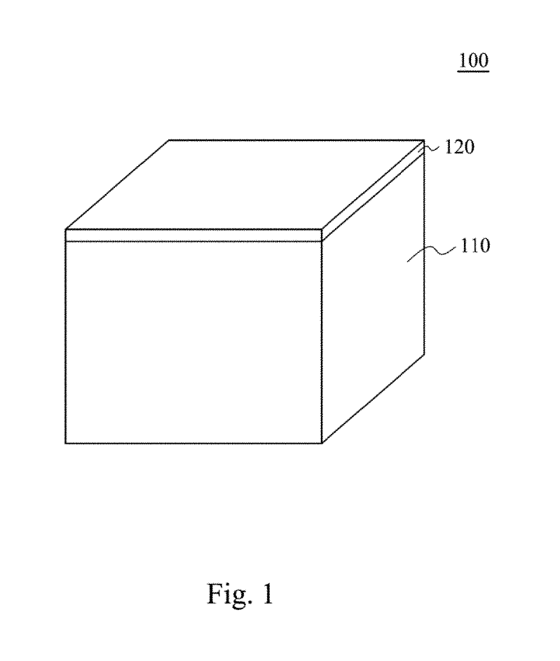

Please refer to FIG. 1. FIG. 1 illustrates a perspective view of a thermoelectric structure 100 according to some embodiments of the present disclosure. As shown in FIG. 1, a thermoelectric substrate 110 is coated with a barrier layer 120, and a material of the barrier layer 120 is metallic glass.

The metallic glass is an amorphous material. When the metallic glass is used as a barrier layer 120 of a thermoelectric module at medium temperature (about 400K to about 800K), it can effectively prevent the diffusion of atoms between the barrier layer 120 and the thermoelectric substrate 110 during the prolonged annealing process at a temperature over the medium temperature, and further prevent the diffusion of atoms between the thermoelectric substrate 110 and a electrode (not shown) because of its property of grain boundary free.

In addition, the present disclosure used the metallic glass as the barrier layer 120 has another advantage. Since the metallic glass has a great barrier property, the thickness of the barrier layer 120 made of the metallic glass is only about 50 nm to 200 nm, preferably about 100 nm to 200 nm. The barrier layer 120 made of the metallic glass is thinner than the generally crystalline barrier layer, so that it can reduce the cost of commercially thermoelectric modules and enhance its applicability.

In some embodiments of the present disclosure, the main ingredient of the metallic glass includes zirconium (Zr), iron (Fe), titanium (Ti), nickel (Ni), tungsten (W) and a combination thereof. The definition of “main ingredient” represents that such main ingredient of all the ingredients of the metallic glass is greater than or equal to 40at % (atomic percentage).

In some embodiments of the present disclosure, when the main ingredient of the metallic glass is zirconium (Zr), the metallic glass is selected from a group consisting of ZrCu, ZrCuAlNi, ZrCuAlAg, ZrCuAlTa, ZrTiCuNiBe, ZrCuAlNiNb, ZrTiCuNiAl, ZrCuAl, ZrNiAl, ZrTiBe and ZrYAlNi.

In some embodiments of the present disclosure, when the main ingredient of the metallic glass is iron (Fe), the metallic glass is selected from a group consisting of FeMoCB, FeZrB, FePBSi, FeAlGaPCB, FeBY, FeBNb and FeCrMoCB.

In some embodiments of the present disclosure, when the main ingredient of the metallic glass is titanium (Ti), the metallic glass is selected from a group consisting of TiHfNiCu, TiNiCu, TiZrNiCuBe and TiZrCuNbCo.

In some embodiments of the present disclosure, when the main ingredient of the metallic glass is nickel (Ni), the metallic glass is selected from a group consisting of NiNb, NiFeNbSn, NiNbSn and NiZrTiSiSn.

In some embodiments of the present disclosure, when the main ingredient of the metallic glass is tungsten (W), the metallic glass is selected from a group consisting of WSiN, WRuB, WReB and WNiB.

In some embodiments of the present disclosure, the thermoelectric substrate is selected from a group consisting of PbTe, CoSb₃, AgSbTe₂, Zn₄Sb₃ Pb—Ag—Sb—Te, GeTe, Te—Sb—Ge—Ag, Ag—Bi—Se—Ge, AgSbSeₓTe₂₋ₓ and YbₓCo₄Sb₁₂, and 0≦x≦1.

The two following embodiments more clearly describe the differences between the thermoelectric structure 100 of the present disclosure and the thermoelectric structure made of generally crystalline barrier layer. The following embodiments are only exemplary, but not intended to limit the present disclosure. One person skilled in the art may elastically select the appropriate material of metallic glass in accordance with the actual needs.

### Embodiment 1

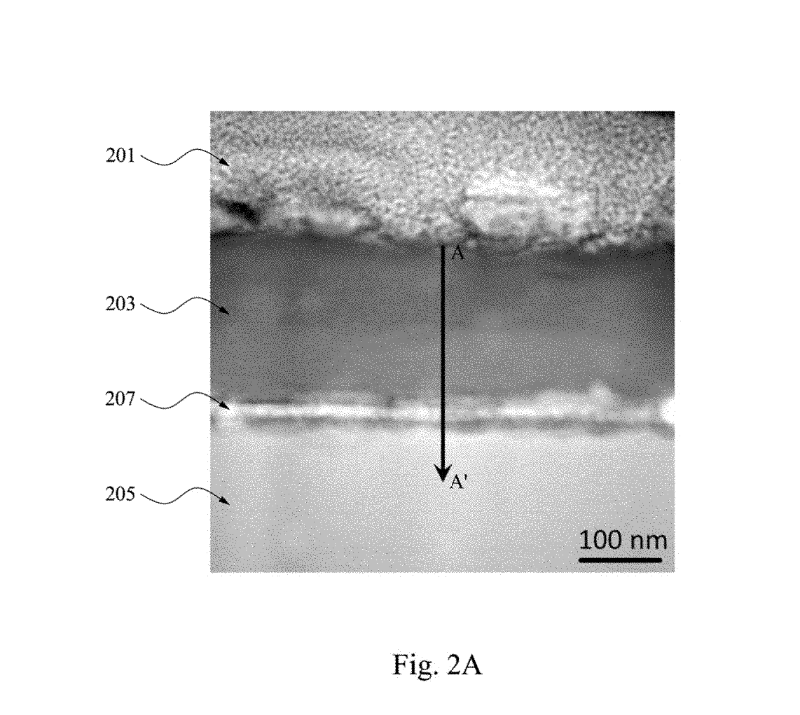

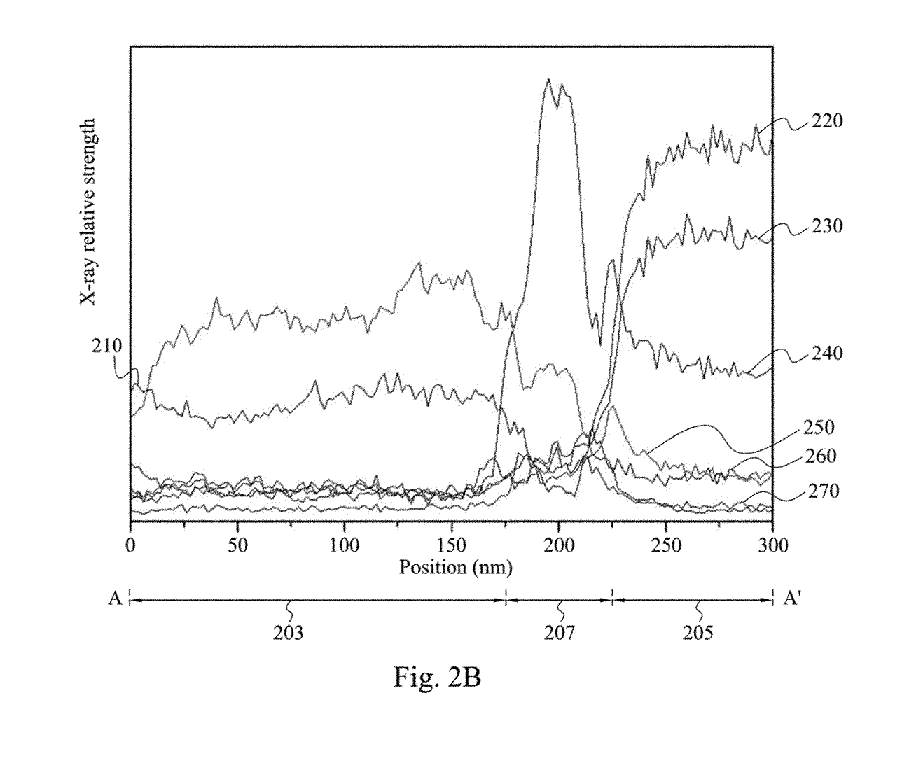

First, AgSbSeₓTe₂₋ₓ(0≦x≦1) was used as a thermoelectric substrate, and the thermoelectric substrate was coated with a barrier layer made of metallic glass (hereinafter referred to as metallic glass barrier layer) having a thickness of 200 nm. The metallic glass could be ZrₐCu_{b}Al_{c}Ni_{d}, a=55±10at %, b=30±5at %, c=10±5at % and d=10±5at %. Next, the thermoelectric substrate coated with the metallic glass (hereinafter referred to as thermoelectric structure A) was annealed at 400° C. under vacuum for 5 days. After annealing 5 days, observed the dark field image of the cross-section transmission electron microscope image (as shown in FIG. 2A) and the ingredient line scan analysis chart (as shown in FIG. 2B).

Please refer to FIG. 2A. FIG. 2A shows a platinum protection layer 201, a metallic glass barrier layer 203 and a thermoelectric substrate 205. The platinum protection layer 201 was coated to protect the top layer while preparing transmission electron microscope specimens. The image of FIG. 2A shows that a thickness of an intermetallic compound 207 formed between the metallic glass barrier layer 203 and the thermoelectric substrate 205 is merely about 50 nm.

In order to know the position of each ingredient in the thermoelectric structure A after above-mentioned annealing process, an ingredient line scan analysis along an arrow A to A′ of FIG. 2A was performed, and the result is showed in FIG. 2B. The horizontal axis of the chart in FIG. 2B corresponds to the position of the arrow A to A′ of FIG. 2A. The position located in a range of 0 to about 175 nm is referred to as the metallic glass barrier layer 203. The position located in a range of about 175 nm to about 225 nm is referred to as the intermetallic compound 207. The position located in a range of about 225 nm to about 300 nm is referred to as the thermoelectric substrate 205. The vertical axis of the chart in FIG. 2B represents the X-ray relative strength of each ingredient in the thermoelectric structure A after above-mentioned annealing process. The lines 210, 220, 230, 240, 250, 260 and 270 respectively represent the X-ray relative strength of zirconium (Zr), tellurium (Te), antimony (Sb), silver (Ag), selenium (Se), oxygen (O) and copper (Cu).

Refer to FIG. 2B. The result of the ingredient analysis shows that the intermetallic compound 207 contains a large amount of silver (Ag), zirconium (Zr) and selenium (Se). In addition, the main ingredients such as silver (Ag), antimony (Sb) and tellurium (Te) of the thermoelectric substrate 205 are not found in the metallic glass barrier layer 203. It can be seen that the atoms of the thermoelectric substrate 205 are not diffused into the metallic glass barrier layer 203. In other words, the metallic glass barrier layer 203 may effectively block the diffusion of the thermoelectric substrate 205 at high temperature.

### Embodiment 2

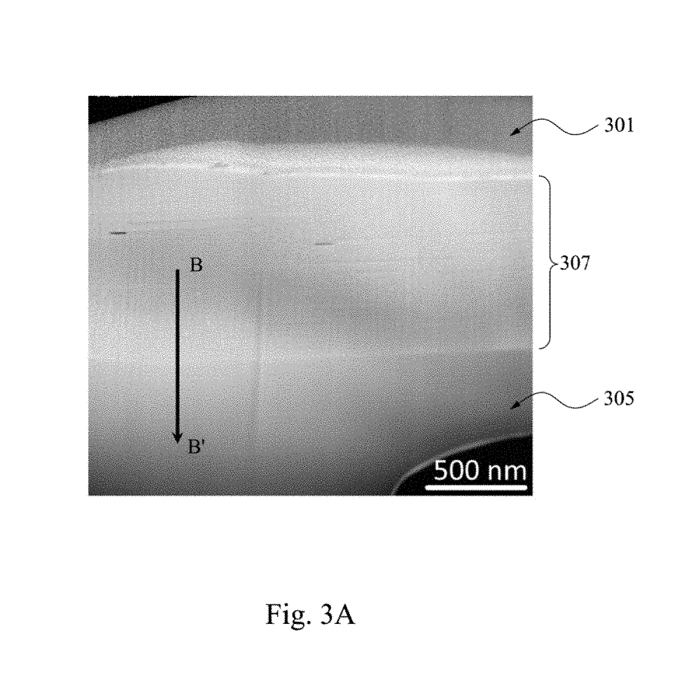

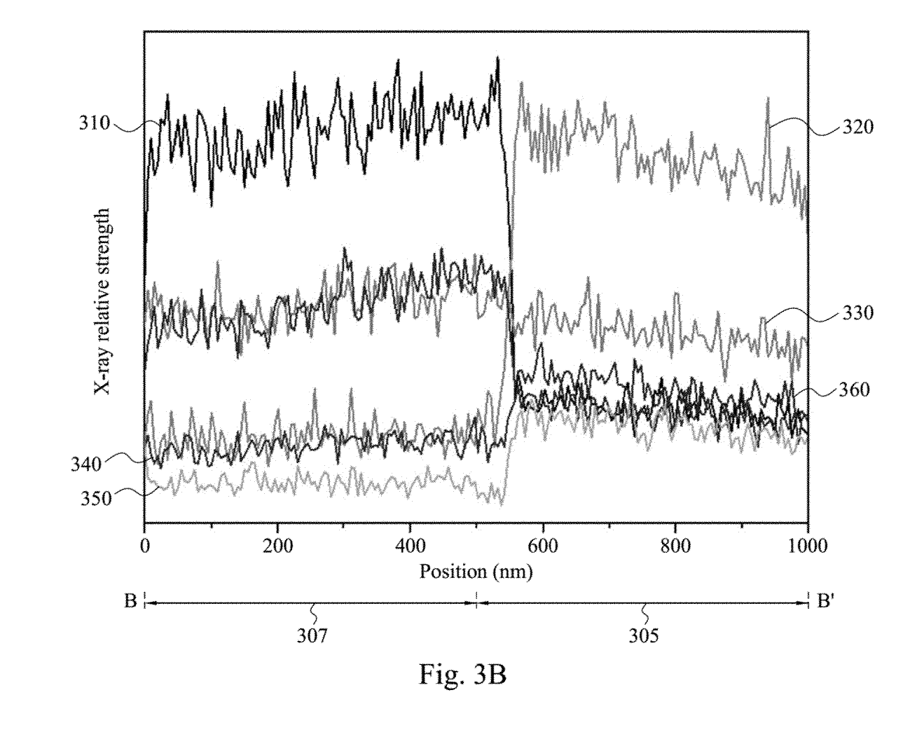

First, AgSbSeₓTe₂₋ₓ(0≦x≦11) was used as a thermoelectric substrate, and the thermoelectric substrate was coated with a barrier layer made of nickel (Ni) (hereinafter referred to as Ni barrier layer) having a thickness of 200 nm. Next, the thermoelectric substrate coated with the Ni barrier layer (hereinafter referred to as thermoelectric structure B) was annealed at 400° C. under vacuum for 5 days. After annealing 5 days, observed the dark field image of the cross-section transmission electron microscope image (as shown in FIG. 3A) and the ingredient line scan analysis chart (as shown in FIG. 3B).

Please refer to FIG. 3A. FIG. 3A shows a platinum protection layer 301, a thermoelectric substrate 305 and an intermetallic compound 307 formed by the interdiffusion of the Ni barrier layer and the thermoelectric substrate. The platinum protection layer 301 was coated to protect the top layer while preparing transmission electron microscope specimens. The image of FIG. 3A shows that the Ni barrier layer has disappeared and replaced by the intermetallic compound 307, which is formed by the interdiffusion of the Ni barrier layer and the thermoelectric substrate and has a thickness about 1000 nm.

In order to know the position of each ingredient in the thermoelectric structure B after above-mentioned annealing process, an ingredient line scan analysis along an arrow B to B′ of FIG. 3A was performed, and the result is showed in FIG. 3B. The horizontal axis of the chart in FIG. 3B corresponds to the position of the arrow B to B′ of FIG. 3A. The position located in a range of 0 to about 500 nm is referred to as the intermetallic compound 307. The position located in a range of about 500 nm to about 1000 nm is referred to as the thermoelectric substrate 305. The vertical axis of the chart in FIG. 3B represents the X-ray relative strength of each ingredient in the thermoelectric structure B after above-mentioned annealing process. The lines 310, 320, 330, 340, 350 and 360 respectively represent the X-ray relative strength of nickel (Ni), silver (Ag), oxygen (O) selenium (Se), antimony (Sb) and tellurium (Te).

Refer to FIG. 3B. The result of the ingredient analysis shows that the intermetallic compound 307 contains a large amount of nickel (Ni), oxygen (O) and tellurium (Te). Because tellurium (Te) is one of the main ingredients of the thermoelectric substrate 305, the result shown in FIG. 3B represents the atoms of the thermoelectric substrate 305 has been diffused into the Ni barrier layer after above-mentioned annealing process and reacted with the Ni barrier layer to produce the intermetallic compound 307. Accordingly, Ni barrier layer can not block the diffusion of the thermoelectric substrate 305 at high temperature.

Please refer to FIGS. 2A-3B. Comparing the distribution positions of each ingredient of the thermoelectric structure A (embodiment 1) and the thermoelectric structure B (embodiment 2) after annealing at 400° C. under vacuum for 5 days, it can be seen that the thermoelectric structure B used general crystalline Ni as a barrier layer can not block the interdiffusion of the thermoelectric substrate 305 and the Ni barrier layer at 400° C. (over 300° C.), and it further causes the reaction of the thermoelectric substrate 305 and the Ni barrier layer to produce the intermetallic compound 307 having a thickness of about 1000 nm. Therefore, if the thermoelectric structure B is applied to a thermoelectric module, the efficiency of the thermoelectric module will be reduced and the reliability and the durability of the thermoelectric module will be damaged. In contrast, the thermoelectric structure A used amorphous metallic glass as a barrier layer of the present disclosure merely generates about 50 nm intermetallic compound 207 between metallic glass barrier layer 203 and thermoelectric substrate 205. Referring to FIGS. 2A and 2B, it also can be seen that the metallic glass barrier layer 203 may effectively block the diffusion of the thermoelectric substrate 205 at 400° C. (over 300° C.).

The embodiments of the present disclosure discussed above have advantages over existing thermoelectric structure, and the advantages are summarized below. The present disclosure provides a thermoelectric structure used metallic glass as a barrier layer. The thermoelectric structure used metallic glass as a barrier layer can effectively block the diffusion of the thermoelectric substrate at over 300° C. When the above-mentioned thermoelectric structure is applied to a medium-temperature (about 400K to about 800K) thermoelectric module, it can effectively avoid the atoms diffusion between the barrier layer and the thermoelectric substrate, and further prevent the atoms diffusion between the thermoelectric substrate and the electrode, so as to maintain the great reliability and durability of the medium-temperature thermoelectric module. In addition, the barrier layer made of the metallic glass is thinner than the generally crystalline barrier layer, so that it can reduce the cost of commercially thermoelectric modules and enhance its applicability.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A thermoelectric structure comprising:
a thermoelectric substrate; and
a barrier layer covering the thermoelectric substrate, wherein a material of the barrier layer is metallic glass.

2. The thermoelectric structure of claim 1, wherein the metallic glass comprises zirconium (Zr), iron (Fe), titanium (Ti), nickel (Ni), tungsten (W) and a combination thereof.

3. The thermoelectric structure of claim 2, wherein the metallic glass is selected from a group consisting of ZrCu, ZrCuAlNi, ZrCuAlAg, ZrCuAlTa, ZrTiCuNiBe, ZrCuAlNiNb, ZrTiCuNiAl, ZrCuAl, ZrNiAl, ZrTiBe and ZrYAlNi.

4. The thermoelectric structure of claim 2, wherein the metallic glass is selected from a group consisting of FeMoCB, FeZrB, FePBSi, FeAlGaPCB, FeBY, FeBNb and FeCrMoCB.

5. The thermoelectric structure of claim 2, wherein the metallic glass is selected from a group consisting of TiHfNiCu, TiNiCu, TiZrNiCuBe and TiZrCuNbCo.

6. The thermoelectric structure of claim 2, wherein the metallic glass is selected from a group consisting of NiNb, NiFeNbSn, NiNbSn and NiZrTiSiSn.

7. The thermoelectric structure of claim 2, wherein the metallic glass is selected from a group consisting of WSiN, WRuB, WReB and WNiB.

8. The thermoelectric structure of claim 1, wherein the metallic glass is ZrₐCu_{b}Al_{c}Ni_{d}, a=55±10at %, b=30±5at %, c=10±5at % and d=10±5at %.

9. The thermoelectric structure of claim 1, wherein the barrier layer has a thickness in a range of 50 nm to 200 nm.

10. The thermoelectric structure of claim 1, wherein the thermoelectric substrate is selected from a group consisting of PbTe, CoSb₃, AgSbTe₂, Zn₄Sb₃ Pb—Ag—Sb—Te, GeTe, Te—Sb—Ge—Ag, Ag—Bi—Se—Ge, AgSbSeₓTe₂₋ₓ and YbₓCo₄Sb₁₂, and 0≦x≦1.
